(19) United States
(12) Patent Application Publication
(10) Pub. No.: US 2024/0203805 A1
(43) Pub. Date: Jun. 20, 2024

(54) EMBEDDED MEMORY FOR GLASS CORE PACKAGES

(71) Applicant: Intel Corporation, Santa Clara, CA (US)

(72) Inventors: Mohammad Mamunur RAHMAN, Gilbert, AZ (US); Brandon C. MARIN, Gilbert, AZ (US); Gang DUAN, Chandler, AZ (US)

(21) Appl. No.: 18/084,275

(22) Filed: Dec. 19, 2022

(51) Int. Cl. H01L 23/15; H01L 23/00; H01L 23/498; H01L 23/538; H01L 25/065

(52) U.S. Cl. CPC H01L 23/15; H01L 23/49816; H01L 23/5384; H01L 24/16; H01L 24/32; H01L 24/73; H01L 25/0655; G06F 12/0897

(57) ABSTRACT

Embodiments disclosed herein include electronic package packages. In an embodiment, the electronic package comprises a package substrate. In an embodiment, a first die is embedded in the package substrate, and a second die is over the package substrate. In an embodiment, the first die is entirely within a footprint of the second die.

### TECHNICAL FIELD

Embodiments of the present disclosure relate to electronic packages, and more particularly to packaging architectures with embedded memory for improved performance.

### BACKGROUND

In advanced packaging architectures, dies are coupled together by bridge dies that are embedded in the package substrate. The use of bridge dies allows for the overlying dies to have a smaller footprint which improves yield of the overlying dies. In addition to stitching together multiple dies, advances in computing performance may rely on the ability to provide memory close to the computing cores of the package architecture. In some instances memory is stacked on top of the die with a hybrid bonding approach. However, such solutions are expensive and increase the Z-height of the electronic package.

Additional architectures may use a base die that is provided below overlying compute dies. The base die couples together the overlying compute dies. In such instances, the base die may be an active component, and memory can be integrated into the larger base die. However, it is expensive to add in memory to the base die.

### BRIEF DESCRIPTION OF THE DRAWINGS

FIG. 1A is a cross-sectional illustration of an electronic package that includes a compute die with an embedded memory die below the compute die, in accordance with an embodiment.

FIG. 1B is a plan view illustration of the electronic package in FIG. 1A, in accordance with an embodiment.

FIG. 2A is a cross-sectional illustration of an electronic package that includes a pair of compute dies that are coupled together by a bridge die and a pair of embedded memory dies below the compute dies, in accordance with an embodiment.

FIG. 2B is a plan view illustration of the electronic package in FIG. 2A, in accordance with an embodiment.

FIG. 3 is a cross-sectional illustration of an electronic package that includes a compute die with an underlying memory die that includes a through silicon via (TSV), in accordance with an embodiment.

FIGS. 4A-4F are cross-sectional illustrations depicting a process for forming an electronic package with an overlying compute die and an embedded memory die, in accordance with an embodiment.

FIG. 5 is a cross-sectional illustration of a computing system that comprises a board with a package substrate that includes embedded memory dies below compute dies, in accordance with an embodiment.

FIG. 6 is a schematic of a computing device built in accordance with an embodiment.

### EMBODIMENTS OF THE PRESENT DISCLOSURE

Described herein are packaging architectures with embedded memory for improved performance, in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

As noted above, the ability to position memory close to the computing cores of dies is desirable in order to improve performance of the system. Previous solutions have included hybrid bonding memory directly to the compute dies, or using integrated memory in large base dies below the compute dies. However, such solutions tend to be more expensive, and results in high cost systems.

Accordingly, embodiments disclosed herein include electronic packages where the memory dies are embedded in the package substrate. This allows for memory to be placed directly below processing cores of the overlying dies. Additionally, embodiments disclosed herein use assembly operations similar to those used to form embedded bridges. As such, the embedded bridges and the memory components can be integrated into the system substantially in parallel and enables cost savings.

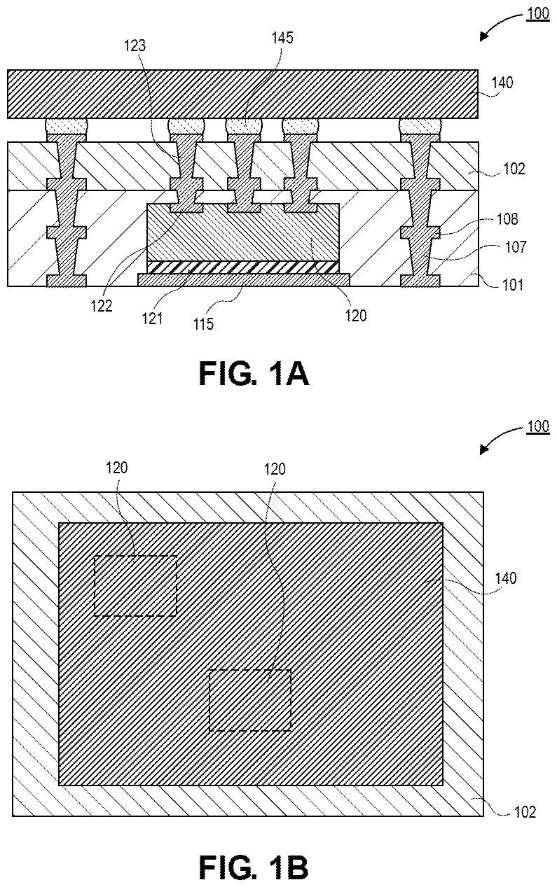

Referring now to FIG. 1A, a cross-sectional illustration of an electronic package 100 is shown, in accordance with an embodiment. In an embodiment, the electronic package 100 may comprise a package substrate 101. The package substrate 101 may be an organic substrate, such as a plurality of organic buildup film layers. In an embodiment, the package substrate 101 may be provided over a core (not shown). The core may be a glass core in some embodiments. The package substrate 101 may include conductive routing, such as pads 108, vias 107, traces, and the like. The conductive routing may comprise electrically conductive material, such as copper. Seed layers, diffusion barrier layers, and the like may also be included in the conductive routing.

In an embodiment, a cavity may be provided in the package substrate 101. A bottom of the cavity may be lined by an etchstop layer or pad 115. The cavity may be at least partially filled by a die 120. The die 120 may be a memory component. In a particular embodiment, the die 120 may be an L3 cache or any other type of cache memory that is used by an overlying compute die 140. The die 120 may include any type of memory, such as DRAM, SRAM, DDR SRAM, etc. The die 120 may be attached to the pad 115 by an adhesive layer 121 or the like. In other embodiments, the die 120 may directly contact the pad 115. In an embodiment, the die 120 may include top pads 122. The top pads 122 may be electrically coupled to the overlying compute die 140 by vias 123 and the like. The vias 123 may pass through an upper package substrate layer 102 and/or a solder resist layer. First level interconnects (FLIs) 145 may couple the vias 123 to the overlying compute die 140.

In an embodiment, the compute die 140 may be any type of compute die. For example, the compute die 140 may include a microprocessor, a graphics processor, a system on a chip (SoC), an application specific integrated circuit (ASIC), or the like. In an embodiment, the compute die 140 may have a footprint that is larger than a footprint of the die 120. As used herein, a die “footprint” may refer to the outer perimeter of the die as viewed from a plan view of the top surface of the device. In the illustrated embodiment, a footprint of the die 120 is entirely within a footprint of the compute die 140. That is, when looking from above, the die 120 is entirely hidden from view by the overlying compute die 140. In the illustrated embodiment, a single die 120 is provided within the footprint of the compute die 140. However, it is to be appreciated that multiple dies 120 may be provided within the footprint of the compute die 140, depending on the memory needs of the electronic package 100.

In an embodiment, the die 120 may be positioned under a computing core of the compute die 140. That is, the region of the compute die 140 that needs additional memory can have memory closely available through the positioning of the die 120. This enables improved performance. Additionally, embedded die 120 architectures are well established solutions and costs are minimal. As such, high performance computing may be enabled without significant costs increases.

Referring now to FIG. 1B, a plan view illustration of an electronic package 100 is shown, in accordance with an embodiment. As shown, a compute die 140 is provided over the upper package substrate layers 102. In an embodiment, one or more dies 120 may be provided entirely within a footprint of the compute die 140. For example, two dies 120 are shown in FIG. 1B. However, it is to be appreciated that any number of dies 120 may be provided within the footprint of the compute die 140. The dies 120 are shown with dashed lines in order to indicate that the dies 120 are below the compute die 140. The dies 120 may be embedded in underlying package substrate layers (not shown in FIG. 1), similar to the architecture shown in FIG. 1A.

In an embodiment, the compute die 140 may be any type of compute die, such as a microprocessor, a graphics processor, an SoC, an ASIC, or the like. In an embodiment, the compute die 140 may include one or more processing cores. In some embodiments, the processing cores may be provided above the one or more dies 120. The dies 120 may be memory dies and operate in conjunction with the overlying processing cores. In a particular embodiment, the dies 120 may include cache memory, such as L3 cache memory in some embodiments.

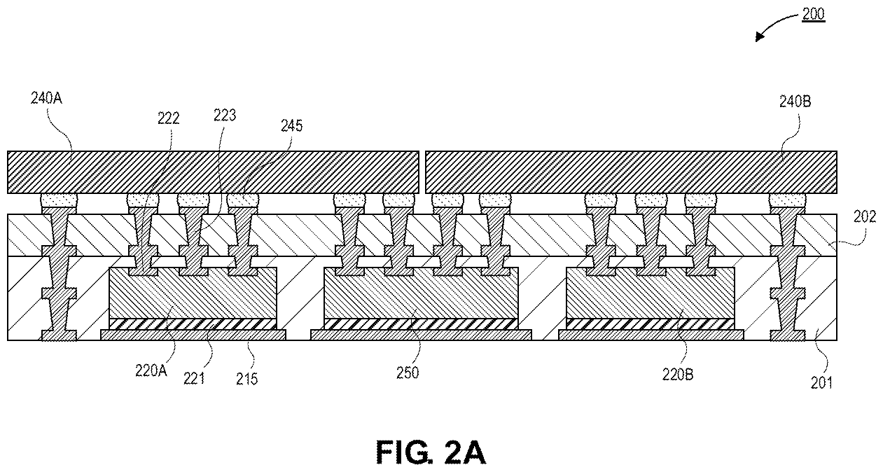

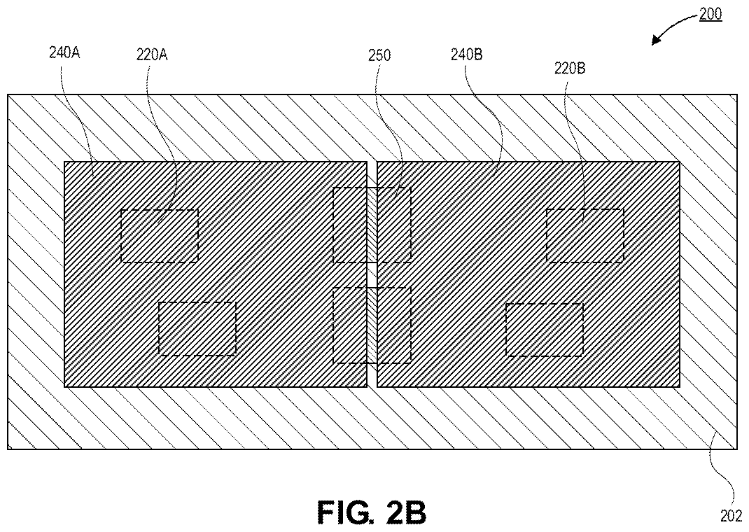

Referring now to FIG. 2A, a cross-sectional illustration of an electronic package 200 is shown, in accordance with an embodiment. In an embodiment, the electronic package 200 comprises a package substrate 201, such as organic buildup film layers. In an embodiment, a plurality of dies 220A, 220B, and 250 may be embedded in the package substrate 201. In an embodiment, the dies 220A, 220B, and 250 may be positioned over pads 215. In an embodiment, the dies 220A, 220B, and 250 may be secured to the pads 215 by an adhesive 221 or the like.

In an embodiment, the dies 220A, 220B, and 250 may be coupled to overlying compute dies 240A and 240B by pads 222, vias 223, and FLIs 245. The conductive routing between the dies 220A, 220B, and 250 and the compute dies 240A and 240B may pass through upper package layers 202 and/or solder resist. In an embodiment, conductive routing may also be provided through the package substrate 201, similar to embodiments described in greater detail above. In an embodiment, only a top portion of the electronic package 200 is shown for simplicity. In other embodiments, there may be a core and lower package substrate layers under the core. The core may comprise glass in some embodiments.

In an embodiment, the dies 220A and 220B may be memory dies. In a particular embodiment, the memory dies 220A and 220B may be L3 cache memory components. The memory dies 220A and 220B may be entirely within a footprint of the overlying compute dies 240A and 240B. For example, die 220A is entirely within a footprint of compute die 240A, and die 220B is entirely within a footprint of compute die 240B. In an embodiment, the dies 220A and 220B may be provided under processing cores of the overlying compute dies 240A and 240B. In an embodiment, the memory die 220A is substantially similar to the memory die 220B. Though, it is to be appreciated that different memory architectures (e.g., memory capacities, etc.) can be implemented in the memory dies 220A and 220B.

In an embodiment, the die 250 may be a bridge die. That is, the die 250 may include high density routing that communicatively couples the first compute die 240A to the second compute die 240B. In an embodiment, the die 250 may be partially within the footprint of the first die 240A and partially within the footprint of the second die 240B. In some embodiments, a portion of the die 250 may be exposed between the first compute die 240A and the second compute die 240B.

In an embodiment, the bridge die 250 may be similar in structure to the memory dies 220A and 220B. For example, a thickness of the bridge die 250 may be substantially similar to a thickness of the memory dies 220A and 220B. As such, trenches with uniform thicknesses may be provided in the package substrate 201 in order to embed the dies 220A, 220B, and 250. This simplifies the assembly process and can reduce costs. Additionally, since bridge dies 250 are already needed in the electronic package 200, assembly processes are not made significantly more complex or costly when memory dies 220A and 220B are also added to the process flow.

Referring now to FIG. 2B, a plan view illustration of the electronic package 200 in FIG. 2A is shown, in accordance with an embodiment. In an embodiment, a pair of compute dies 240A and 240B are provided over the upper layers 202 of a package substrate. As shown, the compute die 240A is communicatively coupled to the compute die 240B by a pair of bridge dies 250. While two bridge dies 250 are shown, it is to be appreciated that one or more bridge dies 250 may be used to couple together the compute dies 240A and 240B.

Additionally, a plurality of memory dies 220A and 220B may be provided within a footprint of the compute dies 240A and 240B. For example, a pair of memory dies 220A are provided within the footprint of the compute die 240A, and a pair of memory dies 220B are provided within the footprint of the compute die 240B. While pairs of memory dies 220A and 220B are shown, it is to be appreciated that one or more memory dies 220 may be provided below each of the compute dies 240A and 240B. Additionally, while shown as being mirror image layouts, the memory dies 220A may have any layout compared to the layout of the memory dies 220B. Further, the number of memory dies 220A below the first compute die 240A may be different than the number of memory dies 220B below the second compute die 240B.

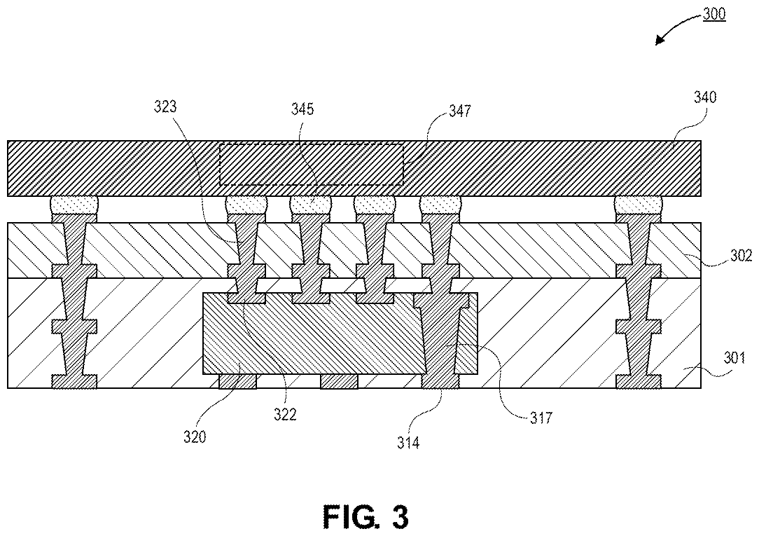

Referring now to FIG. 3, a cross-sectional illustration of an electronic package 300 is shown, in accordance with an additional embodiment. The electronic package 300 may comprise a package substrate 301, such as a plurality of organic buildup film layers. Conductive routing may be provided through the package substrate 301. In an embodiment, the package substrate 301 may be provided over a core (not shown), such as a glass core. In an embodiment, upper layers 302 and/or solder resist may be provided over the package substrate 301.

In an embodiment, a memory die 320 is embedded in the package substrate 301. The memory die 320 may be entirely within a footprint of the overlying compute die 340. In an embodiment, the memory die 320 may be an L3 cache, any other cache type, or any other memory configuration. In an embodiment, pads 322 on the top of the memory die 320 may be coupled to the compute die 340 through vias 323, pads, and FLIs 345. In an embodiment, the memory die 320 may be located below a computing core 347 in the compute die 340. The computing core 347 may be a region of the compute die 340 that performs computational functions, and has easy access to external memory, such as that of memory die 320. In a particular embodiment, the computing core 347 may be a graphics processing core.

The memory die 320 may have a width that is greater than the width of the computing core 347. That is, the memory die 320 may have a footprint that entirely overlaps a footprint of the computing core 347. In order to maximize functional area of the electronic package 300, a through silicon via (TSV) 317 may be provided through the memory die 320. The TSV 317 may contact a bottom pad 314 and provide a path for current through the memory die 320. While shown as directly contacting the bottom pad 314, it is to be appreciated that solder or the like may be provided between the bottom pad 314 and the TSV 317. In an embodiment, the TSV 317 may be a power delivery interconnect that provides power to the overlying compute die 340. While a single TSV 317 is shown, it is to be appreciated that the memory die 320 may have any number of TSVs 317. Generally, the TSVs 317 may be provided proximate to an edge of the memory die 320. More particularly, the TSVs 317 are provided outside of a footprint of the computing core 347.

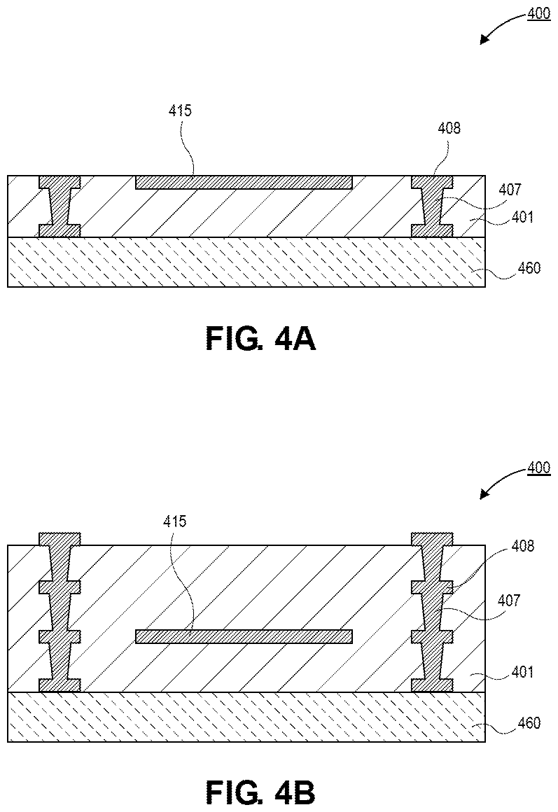

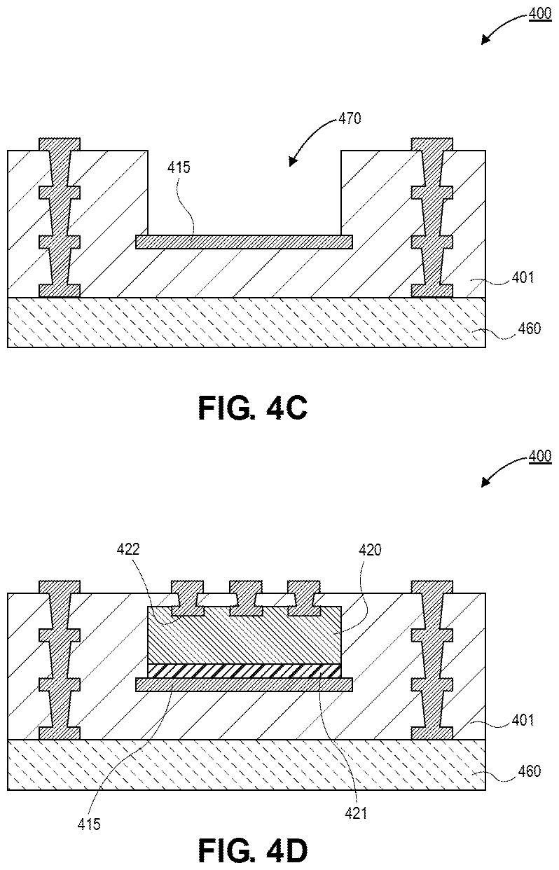

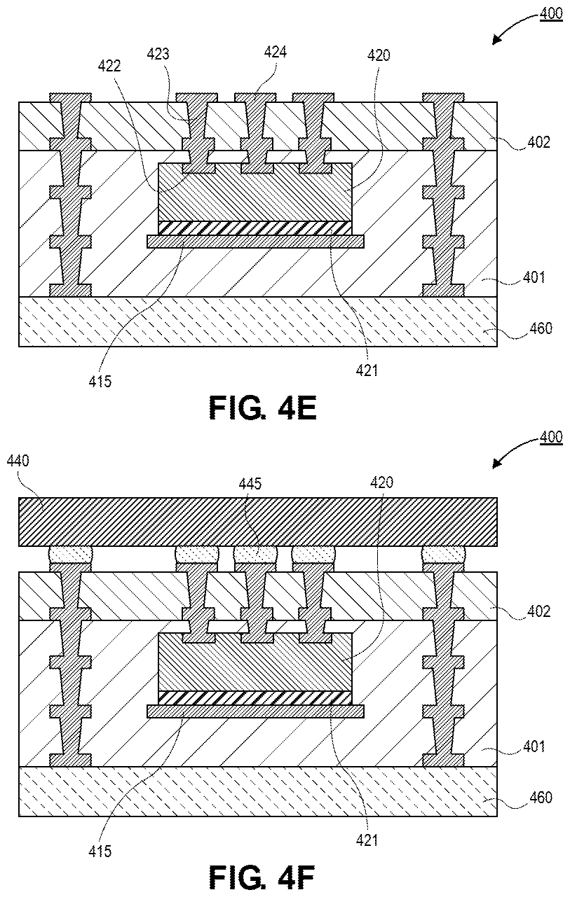

Referring now to FIGS. 4A-4F, a series of cross-sectional illustrations depicting a process for forming an electronic package 400 is shown, in accordance with an embodiment. In an embodiment, the electronic package 400 in FIGS. 4A-4F is similar to the electronic package 100 in FIG. 1A. Though, it is to be appreciated that modifications to the process flow in FIGS. 4A-4F may be made in order to provide electronic packages similar to any of the embodiments described in greater detail herein.

Referring now to FIG. 4A, a cross-sectional illustration of an electronic package 400 at a stage of manufacture is shown, in accordance with an embodiment. In an embodiment, the electronic package 400 comprises a core 460. In an embodiment, the core 460 may include any core material or materials. In one instance, the core 460 may be a glass core. Through glass vias (not shown) may provide connections through the core 460. In other embodiments, the core 460 may be an organic core, such as a glass fiber reinforced substrate. In such embodiments, plated through holes may be provided through the core 460.

In the illustrated embodiment, package substrate layers 401 are provided over the top surface of the core 460. While not shown for simplicity, it is to be appreciated that package substrate layers may also be provided below the core 460. Conductive routing, (e.g., pads 408, vias 407, traces, etc.) may be provided in the package substrate layers 401. The package substrate layers 401 may be dielectric materials such as organic buildup film layers.

In an embodiment, a pad 415 may be provided along an upper surface of the package substrate layers 401. The pad 415 may be used as an etchstop layer for the bottom of a cavity that is formed in a subsequent processing operation. That is, the pad 415 may be structural in nature, and may not be electrically coupled to any of the circuitry of the electronic package 400. In other embodiments, (e.g., when the TSVs are formed through the memory die), the pad 415 may include pads for coupling with the TSV.

Referring now to FIG. 4B, a cross-sectional illustration of the electronic package 400 after additional buildup layers are provided for the package substrate layers 401 is shown, in accordance with an embodiment. In an embodiment, the additional package substrate layers 401 may be used to embed the pad 415 and provide a thickness that is similar to the ultimate thickness of the memory dies that will be added in a subsequent processing operation. The additional package substrate layers 401 may be applied with a lamination process, or the like. Additionally, pads 408, traces, and vias 407 may be patterned into the additional package substrate layers 401. However, a voided region (i.e., without conductive routing) may be provided over the pad 415.

Referring now to FIG. 4C, a cross-sectional illustration of the electronic package 400 after a cavity 470 is formed in the package substrate layers 401 is shown, in accordance with an embodiment. In an embodiment, the cavity 470 may be formed through the package substrate layers 401 in order to expose the pad 415 that was buried by the package substrate layers 401. In an embodiment, a width of the cavity 470 may be narrower than a width of the pad 415. That is, in some instances the ends of the pad 415 may remain covered by the package substrate layers 401. In the illustrated embodiment, the cavity 470 has substantially vertical sidewalls. Though, in other instances, the sidewalls of the cavity 470 may be sloped. For example, a top of the cavity 470 may be wider than a bottom of the cavity 470.

In an embodiment, the cavity 470 may be formed with any suitable patterning process. In one embodiment, the cavity 470 is formed with an etching process, such as a chemical wet etching process, a dry etching process, or the like. In other embodiments, the cavity 470 may be formed with a laser ablation process.

Referring now to FIG. 4D, a cross-sectional illustration of the electronic package 400 after a memory die 420 is inserted into the cavity 470 is shown, in accordance with an embodiment. The remaining space of the cavity 470 may be filled with an underfill, an epoxy, or the like. Though, in FIG. 4D the memory die 420 is shown as being substantially the same width as the cavity 470, and there is no additional space. Such a structure may be an idealized depiction. In actual practice, the width of the cavity 470 may be wider than the width of the memory die 420. In an embodiment, the memory die 420 may be attached to the pad 415 with an adhesive 421 or the like. In embodiments with TSVs through the memory die 420, a solder or the like may connect the TSVs to an underlying pad.

In an embodiment, the memory die 420 may be any suitable memory architecture. In a particular embodiment, the memory die 420 may be a source of L3 cache for an overlying compute die that is added in a subsequent processing operation. Though, it is to be appreciated that any level cache or any other memory type may be used for the memory die 420. In an embodiment, the memory die 420 may include top pads 422. The top pads 422 may be covered by portions of the package substrate layers 401 or another insulating material. Vias through the intervening material may provide access from the top of the electronic package 400 to the memory die 420.

Referring now to FIG. 4E, a cross-sectional illustration of the electronic package 400 after additional upper package substrate layers 402 are formed is shown, in accordance with an embodiment. In an embodiment, the upper package substrate layers 402 may be substantially similar to the package substrate layers 401. For example, the upper package substrate layers 402 may comprise buildup film or the like. The upper package substrate layers 402 may also comprise solder resist or the like.

In an embodiment, vias 423 through the upper package substrate layers 402 may couple top pads 424 to the top pads 422 of the memory die 420. Through the use of package substrate layers 401, upper package substrate layers 402, and any underfill or epoxy, the memory die 420 may be substantially embedded in the electronic package 400. That is, a bottom surface of the memory die 420 may be above the core 460, and a top surface of the memory die 420 may be below a top surface of the upper package substrate layers 402. Sidewalls of the memory die 420 may also be covered with buildup film, underfill or the like. Accordingly, the memory die 420 may be surrounded on substantially all surfaces by insulating material.

While not shown, it is to be appreciated that a bridge die structure may also be embedded in the electronic package 400. When bridge dies are included, the bridge die may have a thickness that is substantially similar to a thickness of the memory die 420. As such, cavities 470 and process flows can be executed substantially in parallel with the integration of the memory die. Additionally, while a single memory die 420 is shown in FIGS. 4A-4F, it is to be appreciated that a plurality of memory dies 420 may be integrated into an electronic package 400, similar to other embodiments described in greater detail above.

Referring now to FIG. 4F, a cross-sectional illustration of the electronic package 400 after a compute die 440 is attached to the upper package substrate layers 402 is shown, in accordance with an embodiment. In an embodiment, the compute die 440 may be coupled to pads on the upper package substrate layers 402 with FLIs 445. While shown as solder balls, it is to be appreciated that any FLI architecture may be used for the FLIs 445. In an embodiment, the compute die 440 may be any type of compute die, such as a microprocessor, a graphics processor, an SoC, an ASIC, or the like. The compute die 440 may have a footprint that is larger than a footprint of the memory die 420 below. In a particular embodiment, the memory die 420 may be entirely within a footprint of the compute die 440. The memory die 420 may be communicatively coupled to the compute die 440 through the vias, pads, FLIs 445, and the like.

In an embodiment, the memory die 420 may be provided directly below a compute core of the compute die 440. For example, the width of the compute core may be substantially similar to the width of the memory die 420. In instances where the memory die 420 has a width that is larger than that of the compute core, TSVs may be provided through the memory die 420 in order to provide power through the memory die 420.

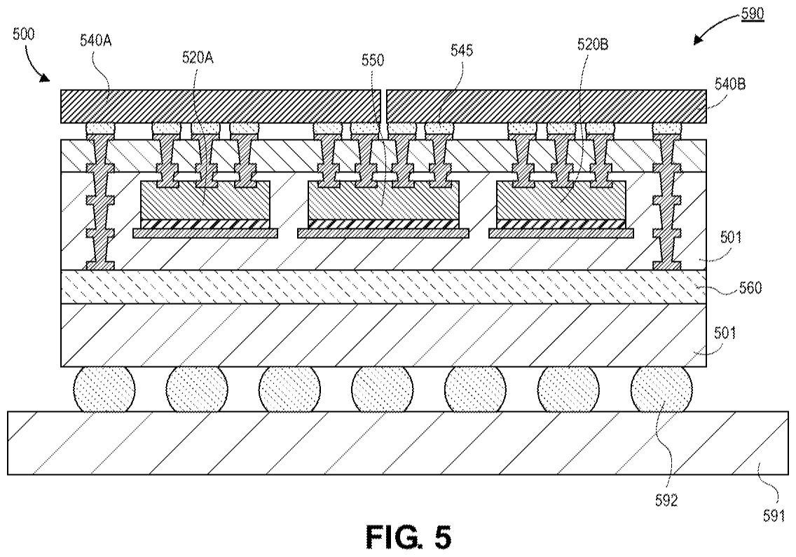

Referring now to FIG. 5, a cross-sectional illustration of a computing system 590 is shown, in accordance with an embodiment. In an embodiment, the computing system 590 may comprise a board 591, such as a printed circuit board (PCB). In an embodiment, the board 591 is coupled to an electronic package 500 by interconnects 592. In an embodiment, the interconnects 592 may be solder balls, sockets or the like.

In an embodiment, the electronic package 500 may comprise a core 560. The core 560 may be a glass core or an organic dielectric with glass fiber reinforcement. Though, any core 560 material may be used in certain embodiments. Package substrate layers 501 may be provided above and below the core 560. The layers above the core 560 are shown as including conductive routing (e.g., pads, traces, vias, etc.), and the backside layers are shown as being voided. Though, it is to be appreciated that conductive routing may also be provided in the package substrate layers 501 below the core 560.

In an embodiment, one or more memory dies 520A and 520B may be embedded in the electronic package 500. The memory dies 520 may be L3 cache, or any other memory architecture. The memory dies 520 may be provided directly below overlying compute dies 540A and 540B. For example, memory die 520A is directly below compute die 540A, and memory die 520B is directly below compute die 540B. More generally, the memory dies 520 are provided entirely within a footprint of the corresponding overlying compute die 540. In an embodiment, the overlying compute dies 540A and 540B may be any type of compute die, such as a microprocessor, a graphics processor, an SoC, an ASIC, or the like.

In an embodiment, the plurality of compute dies 540A and 540B may be communicatively coupled to each other through a bridge die 550. The bridge die 550 may be embedded in the package substrate layers 501. In a particular embodiment, a thickness of the bridge die 550 is substantially similar to a thickness of the memory dies 520. That allows for cavities for the bridge die 550 and the memory dies 520A and 520B to be formed substantially in parallel with each other. Though, in other embodiments the thickness of the memory dies 520A and 520B may be different than the thickness of the bridge die 550. In such instances, shims or other techniques may be used to adjust the heights of the memory dies 520A and 520B or the bridge die 550. In an embodiment, the bridge die 550 is at least partially below the compute die 540A and the compute die 540B. The bridge die 550 may include high density routing in order to communicatively couple together the compute dies 540A and 540B. While a single bridge die 550 is shown, it is to be appreciated that the computing system 590 may include any number of bridge dies 550.

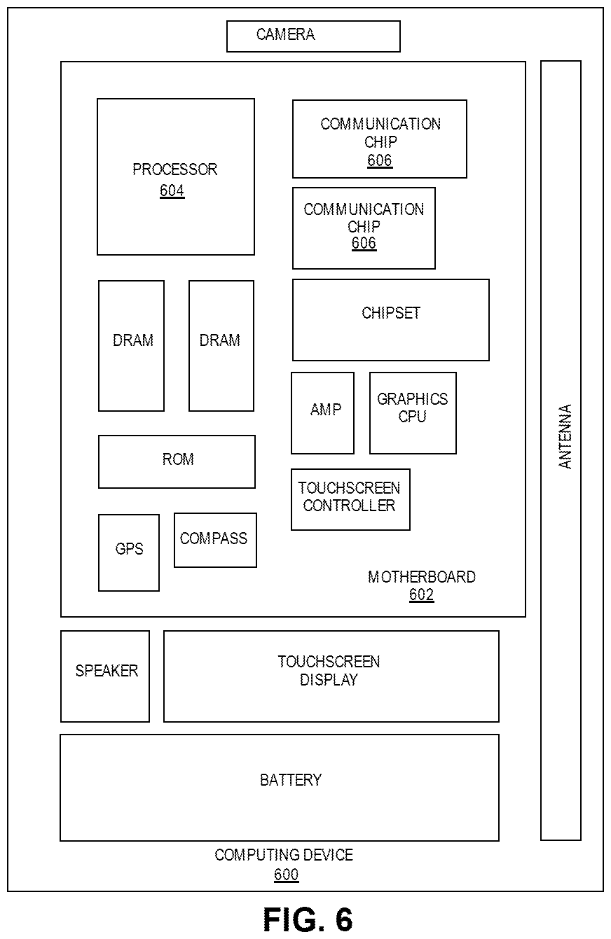

FIG. 6 illustrates a computing device 600 in accordance with one implementation of the invention. The computing device 600 houses a board 602. The board 602 may include a number of components, including but not limited to a microprocessor 604 and at least one communication chip 606. The microprocessor 604 is physically and electrically coupled to the board 602. In some implementations the at least one communication chip 606 is also physically and electrically coupled to the board 602. In further implementations, the communication chip 606 is part of the microprocessor 604.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 606 enables wireless communications for the transfer of data to and from the computing device 600. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 606 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 600 may include a plurality of communication chips 606. For instance, a first communication chip 606 may be dedicated to shorter range wireless communications such as Wi-Fi and Bluetooth and a second communication chip 606 may be dedicated to longer range wireless communications such as GPS, EDGE, GPRS, CDMA, WiMAX, LTE, Ev-DO, and others.

The processor 604 of the computing device 600 includes an integrated circuit die packaged within the processor 604. In some implementations of the invention, the integrated circuit die of the processor may be part of an electronic package that comprises an embedded memory die within a footprint of the processor, in accordance with embodiments described herein. The term “processor” may refer to any device or portion of a device that processes electronic data from registers and/or memory to transform that electronic data into other electronic data that may be stored in registers and/or memory.

The communication chip 606 also includes an integrated circuit die packaged within the communication chip 606. In accordance with another implementation of the invention, the integrated circuit die of the communication chip may be part of an electronic package that comprises an embedded memory die within a footprint of the communication chip, in accordance with embodiments described herein.

In an embodiment, the computing device 600 may be part of any apparatus. For example, the computing device may be part of a personal computer, a server, a mobile device, a tablet, an automobile, or the like. That is, the computing device 600 is not limited to being used for any particular type of system, and the computing device 600 may be included in any apparatus that may benefit from computing functionality.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: an electronic package, comprising: a package substrate; a first die embedded in the package substrate; and a second die over the package substrate, wherein the first die is entirely within a footprint of the second die.

Example 2: the electronic package of Example 1, wherein the first die is a memory die.

Example 3: the electronic package of Example 2, wherein the memory die is an L3 memory cache.

Example 4: the electronic package of Examples 1-3, wherein the first die is attached to a pad in the package substrate by an adhesive layer.

Example 5: the electronic package of Examples 1-4, wherein the package substrate comprises a core.

Example 6: the electronic package of Example 5, wherein the core comprises glass.

Example 7: the electronic package of Examples 1-6, further comprising: a third die over the package substrate; and a fourth die embedded in the package substrate, wherein the fourth die is within the footprint of the second die and a footprint of the third die.

Example 8: the electronic package of Example 7, wherein a thickness of the fourth die is substantially equal to a thickness of the first die.

Example 9: the electronic package of Example 7 or Example 8, wherein the fourth die is a bridge die that communicatively couples the second die to the third die.

Example 10: the electronic package of Examples 1-9, wherein the package substrate is coupled to a board.

Example 11: an electronic package, comprising: a package substrate with a core, wherein the core comprises glass; a first die over the package substrate; a second die over the package substrate and adjacent to the first die; a third die embedded in the package substrate, wherein the third die is entirely within a footprint of the first die; and a fourth die embedded in the package substrate, wherein the fourth die is within the footprint of the first die and within a footprint of the second die.

Example 12: the electronic package of Example 11, wherein the third die is below a processing core in the first die.

Example 13: the electronic package of Example 12, wherein the processing core is a graphics processing core.

Example 14: the electronic package of Examples 11-13, wherein the third die is a memory die.

Example 15: the electronic package of Example 14, wherein the memory die is an L3 cache.

Example 16: the electronic package of Examples 11-15, wherein a thickness of the third die is substantially equal to a thickness of the fourth die.

Example 17: the electronic package of Examples 11-16, wherein the fourth die is a bridge die that communicatively couples the first die to the second die.

Example 18: a computing system, comprising: a board; an electronic package coupled to the board, wherein the electronic package comprises: a package substrate; a first die embedded in the package substrate, wherein the first die is a memory die; and a second die over the package substrate, wherein the first die is entirely within a footprint of the second die.

Example 19: the computing system of Example 18, further comprising: a display coupled to the second die.

Example 20: the computing system of Example 18 or Example 19, wherein the computing system is part of a personal computer, a server, a mobile device, a tablet, or an automobile.

What is claimed is:

1. An electronic package, comprising:
a package substrate;
a first die embedded in the package substrate; and
a second die over the package substrate, wherein the first die is entirely within a footprint of the second die.

2. The electronic package of claim 1, wherein the first die is a memory die.

3. The electronic package of claim 2, wherein the memory die is an L3 memory cache.

4. The electronic package of claim 1, wherein the first die is attached to a pad in the package substrate by an adhesive layer.

5. The electronic package of claim 1, wherein the package substrate comprises a core.

6. The electronic package of claim 5, wherein the core comprises glass.

7. The electronic package of claim 1, further comprising:
a third die over the package substrate; and
a fourth die embedded in the package substrate, wherein the fourth die is within the footprint of the second die and a footprint of the third die.

8. The electronic package of claim 7, wherein a thickness of the fourth die is substantially equal to a thickness of the first die.

9. The electronic package of claim 7, wherein the fourth die is a bridge die that communicatively couples the second die to the third die.

10. The electronic package of claim 1, wherein the package substrate is coupled to a board.

11. An electronic package, comprising:
a package substrate with a core, wherein the core comprises glass;
a first die over the package substrate;
a second die over the package substrate and adjacent to the first die;
a third die embedded in the package substrate, wherein the third die is entirely within a footprint of the first die; and
a fourth die embedded in the package substrate, wherein the fourth die is within the footprint of the first die and within a footprint of the second die.

12. The electronic package of claim 11, wherein the third die is below a processing core in the first die.

13. The electronic package of claim 12, wherein the processing core is a graphics processing core.

14. The electronic package of claim 11, wherein the third die is a memory die.

15. The electronic package of claim 14, wherein the memory die is an L3 cache.

16. The electronic package of claim 11, wherein a thickness of the third die is substantially equal to a thickness of the fourth die.

17. The electronic package of claim 11, wherein the fourth die is a bridge die that communicatively couples the first die to the second die.

18. A computing system, comprising:
a board;
an electronic package coupled to the board, wherein the electronic package comprises:
a package substrate;
a first die embedded in the package substrate, wherein the first die is a memory die; and
a second die over the package substrate, wherein the first die is entirely within a footprint of the second die.

19. The computing system of claim 18, further comprising:
a display coupled to the second die.

20. The computing system of claim 18, wherein the computing system is part of a personal computer, a server, a mobile device, a tablet, or an automobile.
